(19) United States
(12) Patent Application Publication
(10) Pub. No.: US 2021/0202275 A1
(43) Pub. Date: Jul. 1, 2021

(54) TOOLS AND METHODS FOR SUBTRACTIVE METAL PATTERNING

(71) Applicant: Intel Corporation, Santa Clara, CA (US)

(72) Inventor: Christopher J. Jezewski, Portland, OR (US)

(73) Assignee: Intel Corporation, Santa Clara, CA (US)

(21) Appl. No.: 16/950,630

(22) Filed: Nov. 17, 2020

Related U.S. Application Data
(60) Provisional application No. 62/954,124, filed on Dec. 27, 2019.

(51) Int. Cl. H01L 21/67; H01L 21/683; H01L 23/528; H01L 21/3213; H01J 37/32

(52) U.S. Cl. CPC H01L 21/67069; H01L 21/6831; H01L 23/5283; H01L 21/32136; H01L 23/53228; H01J 37/3255; H01J 37/32715; H01J 37/32669; H01L 21/32139

(57) ABSTRACT

Disclosed herein are tools and methods for subtractively patterning metals. These tools and methods may permit the subtractive patterning of metal (e.g., copper, platinum, etc.) at pitches lower than those achievable by conventional etch tools and/or with aspect ratios greater than those achievable by conventional etch tools. The tools and methods disclosed herein may be cost-effective and appropriate for high-volume manufacturing, in contrast to conventional etch tools.

### CROSS-REFERENCE TO RELATED APPLICATION

This application claims priority to U.S. Provisional Application No. 62/954,124, filed Dec. 27, 2019 and titled “TOOLS AND METHODS FOR SUBTRACTIVE METAL PATTERNING.” This priority application is incorporated by reference herein in its entirety.

### BACKGROUND

Metal-based interconnects may be used to route electrical signals in integrated circuit (IC) devices. For example, such interconnects may be used to electrically couple transistors to perform logic and/or memory operations.

### BRIEF DESCRIPTION OF THE DRAWINGS

Embodiments will be readily understood by the following detailed description in conjunction with the accompanying drawings. To facilitate this description, like reference numerals designate like structural elements. Embodiments are illustrated by way of example, not by way of limitation, in the figures of the accompanying drawings.

FIG. 1 is a side, cross-sectional view of a metal etch tool, in accordance with various embodiments.

FIG. 2 is a side view of an electrode that may be included in the metal etch tool of FIG. 1, in accordance with various embodiments.

FIG. 3 is a side, cross-sectional view of another metal etch tool, in accordance with various embodiments.

FIG. 4 is a top view of an electrode that may be included in the metal etch tool of FIG. 2, in accordance with various embodiments.

FIG. 5 is a side, cross-sectional view of another metal etch tool, in accordance with various embodiments.

FIG. 6 is a top view of an electrode that may be included in the metal etch tool of FIG. 5, in accordance with various embodiments.

FIGS. 7 and 8 illustrate stages in an example process of performing subtractive metal patterning using the tools disclosed herein, in accordance with various embodiments.

FIG. 9 is a flow diagram of a method of using a metal etch tool, in accordance with various embodiments.

FIG. 10 is a top view of a wafer and dies that may include features formed using the metal etch tools and methods disclosed herein, in accordance with various embodiments.

FIG. 11 is a side, cross-sectional view of an integrated circuit (IC) device that may include features formed using the metal etch tools and methods disclosed herein, in accordance with various embodiments.

FIG. 12 is a side, cross-sectional view of an IC package that may include features formed using the metal etch tools and methods disclosed herein, in accordance with various embodiments.

FIG. 13 is a side, cross-sectional view of an IC device assembly that may include features formed using the metal etch tools and methods disclosed herein, in accordance with various embodiments.

FIG. 14 is a block diagram of an example electrical device that may include features formed using the metal etch tools and methods disclosed herein, in accordance with various embodiments.

### DETAILED DESCRIPTION

Conventional subtractive metal patterning (e.g., depositing a blanket layer of metal, forming a patterned template material on the blanket metal, and then removing the metal not covered by the patterned template material) may be used for large metal features, but has not been appropriate for the fabrication of metal structures with small feature sizes in a large-scale commercial setting. Dual damascene-type processes (e.g., depositing and patterning a dielectric material, and then depositing a metal to fill the gaps in the dielectric material and provide metal features) have been used to achieve smaller feature sizes than conventional subtractive metal patterning, but such processes may not meet the needs of the next generation of even smaller electronic devices. For example, metal features with high aspect ratios (e.g., a height to width ratio that is greater than 2:1) may be desirable for reducing resistance-capacitance (RC) delay in backend interconnects of integrated circuit (IC) dies, but features with such aspect ratios may not be reliably manufactured using existing metal gapfill techniques. More recent gapfill techniques, such as electroless metallization, may require a thick, robust underlying metal seed layer, and the formation of such seed layers (e.g., by atomic layer deposition (ALD) or physical vapor deposition (PVD)) in high aspect ratio trenches may suffer from pinch-off voiding (and therefore, the risk of electrical discontinuity). Recent advances in ALD liner materials may reduce the incidence of pinch-off in ALD seed layer deposition, but may require prohibitively thick liners and may result in increased resistance of the resulting features. Other gapfill-related techniques, such as using faceted vias, may require special processing and materials that reduce or eliminate the advantages of such techniques. For example, faceted via techniques may reduce the density of patterned features, and thus the ability to scale, in order to obtain the same electrical performance as vias with “straight” profiles.

Disclosed herein are tools and methods for subtractively patterning metals. These tools and methods may permit the subtractive patterning of metal (e.g., copper, platinum, etc.) at pitches lower than those achievable by conventional etch tools and/or with aspect ratios greater than those achievable by conventional etch tools. The tools and methods disclosed herein may be cost-effective and appropriate for high-volume manufacturing, in contrast to conventional etch tools.

Conventional etch hardware may not be suitable for etching metals, such as copper. Such conventional etch hardware typically includes a chamber with dielectric walls (e.g., walls formed of yttria-stabilized quartz), and electrodes outside of those walls generate radio frequency (RF) electromagnetic waves that couple into the chamber through the dielectric walls to help guide/form a plasma therein. If a metal sample is etched inside such a chamber, the metal removed from the metal sample will redeposit onto the dielectric walls, forming an electrically conductive layer that blocks the RF coupling between the outer electrodes and the interior of the chamber, and thereby rendering the chamber inoperative. Further, conventional chemical cleaning techniques may fail to remove such metal from the chamber walls.

Some of the metal etch tools disclosed herein may share some features with conventional metal thin film sputter chambers (used to deposit metal, not etch it). Conventional sputter chambers may be used to deposit a thin, conformal layer of a metal (e.g., copper) onto a structure; that structure may then be removed from the sputter chamber and the thin layer of metal may be used as a seed layer for an electroplating process to deposit further amounts of the metal, for example. The metal etch tools disclosed herein may differ from conventional sputter chambers in a number of ways, including the use of electrodes inside the chamber that are formed of the same metal that is going to be etched from a sample. When the etched metal redeposits on such electrodes during operation, performance of the metal etch tools disclosed herein may not be compromised (in contrast to the use of conventional etch tools when used to etch metal). The metal etch tools and methods disclosed herein may therefore reliably and repeatedly allow the subtractive patterning of metal to form features smaller than those achievable by conventional large-scale manufacturing tools and techniques, which may improve the RC delay of very small, critical-dimension interconnects that can maximize the volume of metal (e.g., copper) in conductive features, and thereby improve performance.

In the following detailed description, reference is made to the accompanying drawings that form a part hereof wherein like numerals designate like parts throughout, and in which is shown, by way of illustration, embodiments that may be practiced. It is to be understood that other embodiments may be utilized, and structural or logical changes may be made, without departing from the scope of the present disclosure. Therefore, the following detailed description is not to be taken in a limiting sense.

Various operations may be described as multiple discrete actions or operations in turn, in a manner that is most helpful in understanding the claimed subject matter. However, the order of description should not be construed as to imply that these operations are necessarily order dependent. In particular, these operations may not be performed in the order of presentation. Operations described may be performed in a different order from the described embodiment. Various additional operations may be performed, and/or described operations may be omitted in additional embodiments.

For the purposes of the present disclosure, the phrase “A and/or B” means (A), (B), or (A and B). For the purposes of the present disclosure, the phrase “A, B, and/or C” means (A), (B), (C), (A and B), (A and C), (B and C), or (A, B, and C). The drawings are not necessarily to scale. Although many of the drawings illustrate rectilinear structures with flat walls and right-angle corners, this is simply for ease of illustration, and actual devices made using these techniques will exhibit rounded corners, surface roughness, and other features.

The description uses the phrases “in an embodiment” or “in embodiments,” which may each refer to one or more of the same or different embodiments. Furthermore, the terms “comprising,” “including,” “having,” and the like, as used with respect to embodiments of the present disclosure, are synonymous. As used herein, a “package” and an “IC package” are synonymous. When used to describe a range of dimensions, the phrase “between X and Y” represents a range that includes X and Y.

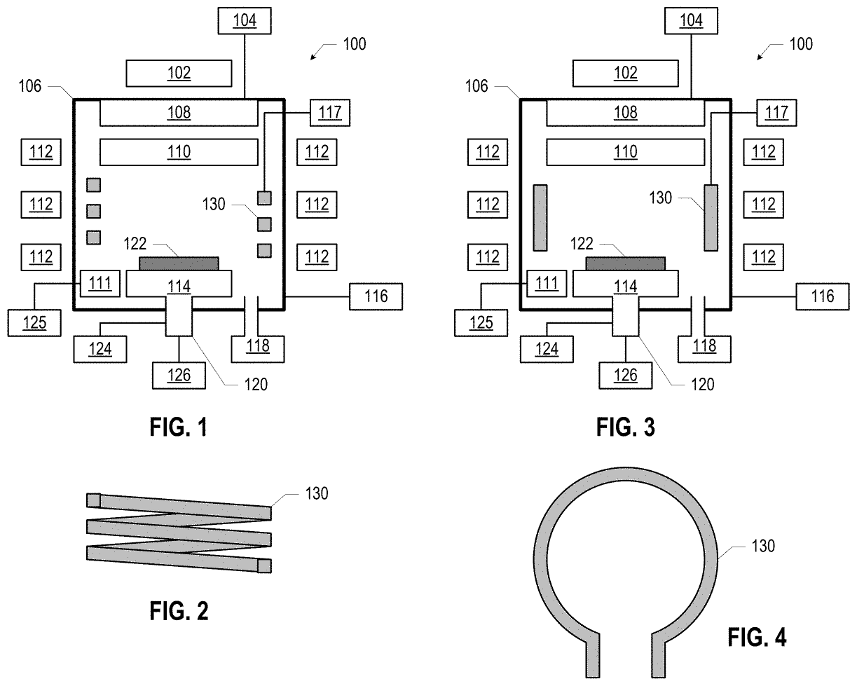

FIG. 1 is a side, cross-sectional view of a metal etch tool 100 with a sample 122 therein, in accordance with various embodiments. The metal etch tool 100 may include a chamber 106 into which an electrostatic chuck 120 extends. In some embodiments, the electrostatic chuck 120 may include alumina or a dielectric material. The electrostatic chuck 120 may include a pedestal 114 on which the sample 122 (including a metal to be etched) is disposed. The electrostatic chuck 120 may be conductively coupled to an AC voltage source 126, which may be controlled (e.g., by the control circuitry 125, discussed below) to provide AC voltages to the electrostatic chuck 120 in any suitable frequency range (e.g., between 300 kilohertz and 60 megahertz, or between 50 kilohertz and 100 megahertz). The electrostatic chuck 120 may also be coupled to a heating/cooling device 124, which may be operated to control the temperature of the electrostatic chuck 120 in any suitable temperature range (e.g., between −60 degrees Celsius and 22 degrees Celsius for low temperature etches, and/or up to 400 degrees Celsius to aid in volatilizing etch products). A heating/cooling device 116 may also be coupled to the chamber 106, and may be operated to control the temperature of the chamber 106 in any suitable temperature range (e.g., up to 400 degrees Celsius to aid in volatilizing etch products).

A pump/gas source 118 may be operated to control the pressure and gas content of the chamber 106. For example, the pump/gas source 118 may include a cryogenic pump and/or a turbo pump and may pump reactive and/or nonreactive gases (e.g., oxygen gas, hydrogen gas, ammonia gas, argon gas, helium gas, neon gas, krypton gas, and/or xenon gas) into the chamber 106. Various species of gas pumped into the chamber 106 by the pump/gas source 118 may perform various functions in an etch process; for example, hydrogen gas may facilitate hydrogen reduction, oxygen plasmas may facilitate anisotropic oxidation, and nitrogen gas may facilitate nitridation. In some embodiments, carbon-containing gases may be used to help shape etch profiles and/or volatilize etch products; examples of such gases may include hydrocarbons (e.g., including CH₃, C₂H₆, or hydrocarbons with greater numbers of carbon atoms), carbon monoxide and/or carbon dioxide (e.g., for forming volatile carbonyl etch products), and alcohols (e.g., methanol or ethanol).

A magnet 102 may be disposed outside the chamber 106, above the sample 122. Inside the chamber 106, between the magnet 102 and the sample 122, a target material 108 may be disposed. The target material 108 may have a same material composition (e.g., may include the same metal) as the metal to be etched from the sample 122. A DC voltage source 104 may be conductively coupled to the target material 108, and may be controlled (e.g., by the control circuitry 125, discussed below) to provide DC voltages to the target material 108 in any suitable voltage range. A collimator 110 may be disposed in the chamber 106 between the target material 108 and the sample 122; in some embodiments, the collimator 110 may aid in changing ion angles to improve etch performance (e.g., to achieve a desired profile shape of the etched metal) and/or clean the interior walls of the chamber 106. Outside the chamber 106, one or more electromagnets 112 may be disposed. The electromagnets 112 may be controlled (e.g., by the control circuitry 125, discussed below) to aid in adjusting the magnetic fields inside the chamber 106 (e.g., serving as Einzel lenses to help focus the collimation of ions and/or to change angles for etch optimization), and may thereby control the plasma inside the chamber 106. In some embodiments, the electromagnets 112 may coil around the outside of the chamber 106.

One or more electrodes 130 may be disposed inside the chamber 106. The electrodes 130 may be conductively coupled to an AC voltage source 117, which may be controlled (e.g., by the control circuitry 125, discussed below) to provide AC voltages to the electrodes 130 in any suitable frequency range (e.g., between 50 kilohertz and 100 megahertz). Like the electromagnets 112, the controllable currents and/or voltages through the electrodes 130 may further aid in the control of the plasma inside the chamber 106. The electrodes 130 may have a same material composition as the metal of the sample 122 to be etched (e.g., copper electrodes 130 may be used to etch copper of the sample 122, platinum electrodes 130 may be used to etch platinum of the sample 122, etc.). The electrodes 130 may aid in the generation of capacitively and/or inductively coupled plasmas for ionizing gases. In the embodiment of FIG. 1, the electrode 130 in the chamber 106 may have a cylindrical coil structure that extends helically in the direction between the sample 122 and the magnet 102; FIG. 2 is a side view of such a cylindrical coil electrode 130 that may be included in the metal etch tool 100 of FIG. 1, in accordance with various embodiments. In some embodiments, a cylindrical coil electrode 130 may include a number of turns between 1 and 12.

One or more sensors 111 may also be disposed within the chamber 106. These sensors 111 may serve to monitor etch conditions inside the chamber 106, and may communicate sensed data to control circuitry 125 outside the chamber 106. The sensors 111 may include any suitable sensor(s), such as a gas sensor (e.g., as part of an optical emission spectroscopy system) and/or a pump (e.g., sensing the presence of volatilized fragments in the chamber 106). The control circuitry 125 (which may, in some embodiments, communicate with the sensors 111 via a fiber optic connection) may include any one or more processing devices programmed to interpret the data from the sensors 111 and generate control signals to control the operation of the metal etch tool 100 (e.g., by controlling the currents/voltages of the electromagnets 112, the electrode(s) 130, the target material 108, and the electrostatic chuck 120; the temperatures of the chamber 106 and the electrostatic chuck 120; the gas content and pressure within the chamber 106, etc.).

Other embodiments of the metal etch tools 100 disclosed herein may include electrodes 130 with various shapes and at various locations within the chamber 106. For example, FIG. 3 is a side, cross-sectional view of another metal etch tool 100, in accordance with various embodiments. The metal etch tool 100 of FIG. 3 shares many elements with the metal etch tool 100 of FIG. 1; these shared elements may take any of the forms disclosed herein, and a discussion of these elements is not repeated. In the metal etch tool 100 of FIG. 3, the electrode 130 may have a band shape that may extend at least partially around the interior of the chamber 106; FIG. 4 is a top view of such a band-shaped electrode 130 that may be included in the metal etch tool 100 of FIG. 2, in accordance with various embodiments.

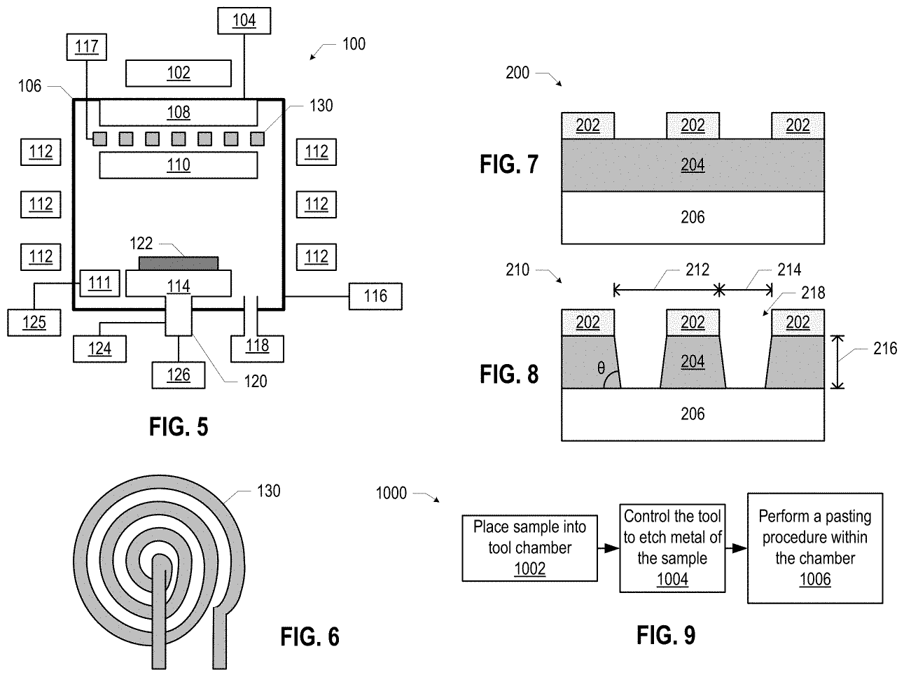

FIG. 5 is a side, cross-sectional view of another metal etch tool 100, in accordance with various embodiments. The metal etch tool 100 of FIG. 5 also shares many elements with the metal etch tool 100 of FIG. 1; these shared elements may take any of the forms disclosed herein, and a discussion of these elements is not repeated. In the metal etch tool 100 of FIG. 5, the electrode 130 may be positioned between the target material 108 and the collimator 110, unlike the electrodes 130 of the metal etch tools of FIGS. 1 and 3 (which are positioned more toward the middle of the chamber 106 in the vertical direction). In some embodiments, the electrode 130 of the metal etch tool 100 of FIG. 5 may be substantially planar (e.g., may be substantially contained in a small, largely planar volume proximate to the target material 108). In some embodiments, the electrode 130 of the metal etch tool 100 of FIG. 5 may have a coil shape; FIG. 6 is a top view of such a planar, coil electrode 130 that may be included in the metal etch tool 100 of FIG. 5, in accordance with various embodiments. In other embodiments, the electrode 130 of the metal etch tool 100 of FIG. 5 may have a shape that is different than a coil (e.g., a serpentine or meandering shape). In some embodiments, a planar, coil electrode 130 may include a number of turns between 1 and 12.

The metal etch tools 100 disclosed herein may be operated similarly to the operation of a conventional sputter chamber, but the parameters of the metal etch tool 100 (e.g., the currents/voltages of the electromagnets 112, the electrode(s) 130, the target material 108, and the electrostatic chuck 120; the temperatures of the chamber 106 and the electrostatic chuck 120; the gas content and pressure within the chamber 106, etc.) may be controlled to increase the ion energies relative to a sputtering process, and change the species in the chamber 106 relative to a sputtering process, to etch the metal of the sample 122, rather than deposit additional metal. The electrodes 130 may also be structured to tune (e.g., increase) inductive and/or capacitive coupling into the plasma.

FIGS. 7 and 8 illustrate stages in an example process of performing subtractive metal patterning using the tools disclosed herein, in accordance with various embodiments. In particular, FIG. 7 is a side, cross-sectional view of an assembly 200 that may be inserted into a metal etch tool 100 as an initial sample 122 (before the metal etch tool 100 has been operated to perform metal etch on the sample 122). The assembly 200 may include a support 206, which may include a semiconductor or silicon-on-insulator (SOI) substrate (e.g., as discussed below with reference to FIG. 11), one or more device layers (e.g., as discussed below with reference to FIG. 11), and/or previous metallization (e.g., as discussed below with reference to FIG. 7). The assembly 20 may also include a metal 204, which may be the metal to be etched in the metal etch tool 100, with a template material 202 thereon. The template material 202 may define the locations at which the metal 204 is to be etched; the metal 204 may be etched in locations not covered by the template material 202. In some embodiments, the template material may be a resist material, such as a photoresist.

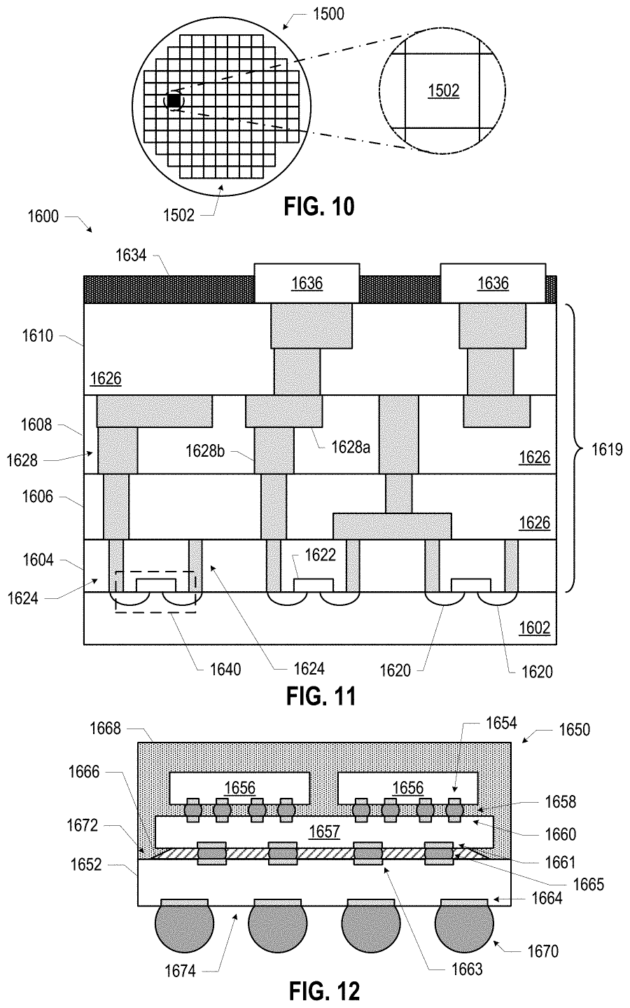

FIG. 8 is a side, cross-sectional view of an assembly 210 subsequent to operating the metal etch tool 100 (e.g., the metal etch tool 100 of any of FIG. 1, 3, or 5) to remove the exposed metal 204 of the assembly 200 (FIG. 7) and to form trenches 218 in the metal 204. As noted above, the electrode(s) 130 in the chamber 106 of the metal etch tool 100 may have a same material composition as the metal 204. The underlying support 206 may act as an etch stop layer, or the etch of the metal 204 may be timed to achieve a desired depth. The remaining metal 204 of FIG. 8 may be interconnect structures, such as metal lines or other metal features (e.g., suitable ones of the interconnect structures 1628 discussed below with reference to FIG. 10). The use of the metal etch tools 100 disclosed herein to perform the etch of the metal 204 may allow the formation of features whose geometries are not readily and cost-effectively achievable using conventional etch tools. For example, in some embodiments, the angle A of the sidewalls of the trenches 218 (equivalent to the angle A of the sidewalls of the remaining metal features 204) may be greater than 82 degrees. In some embodiments, the pitch 212 of the trenches 218 (equivalent to the pitch of the remaining metal features 204) may be less than 40 nanometers (e.g., less than 30 nanometers). In some embodiments, the aspect ratio of the trenches 218 (e.g., the ratio between the height 216 of the trenches 218 and the width or diameter 214 of the trenches 218) may be greater than 2:1 (e.g., greater than 3:1, between 2:1 and 5:1, or between 3:1 and 5:1).

FIG. 9 is a flow diagram of a method 1000 of using a metal etch tool 100, in accordance with various embodiments. Operations are illustrated once each and in a particular order in FIG. 9, but the operations may be reordered and/or repeated as desired (e.g., with different operations performed in parallel when etching multiple samples 122 simultaneously).

At 1002, a sample may be placed into a tool chamber. Electrodes, having a same material composition as the metal of the sample to be etched, may be located in the chamber. For example, a sample 122 may be placed on a pedestal 114 in a chamber 106 of a metal etch tool 100; electrode(s) 130 of the metal etch tool 100 may have a same material composition as the metal to be etched from the sample 122.

At 1004, the tool may be controlled to etch the metal of the sample. For example, parameters that may be controlled (e.g., via the control circuitry 125) may include: the currents/voltages of the electromagnets 112, the electrode(s) 130, the target material 108, and the electrostatic chuck 120; the temperatures of the chamber 106 and the electrostatic chuck 120; and the gas content and pressure within the chamber 106. These parameters may be controlled to create an etching plasma within the metal etch tool 100 (e.g., by increasing ion energies to principally etch, as discussed above). Etch of the metal of a sample may include bombarding the metal of the sample with ions to knock the metal atoms off the sample 122 (and onto the walls of the chamber 106, the electrode(s) 130, etc.), as discussed above.

At 1006, a pasting procedure may be performed within the chamber. A pasting procedure may include putting a metal sample, having the same material composition as the metal etched at 2004, onto the pedestal 114 in the chamber 106, and performing another etch process to cause a substantial amount (or all) of the metal sample to be distributed within the chamber 106 (e.g., on the walls of the chamber 106, on the electrode(s) 130, etc.). This pasting procedure may provide a relatively smooth, homogeneous coating of the metal onto these surfaces, “pasting” down any impurities, flakes, or other undesirable structures within the chamber 106 and improving the condition of the interior of the chamber 106 for subsequent etch processes. In some embodiments, a pasting procedure may not be performed after each round of metal etching, but after a predetermined time period, a predetermined number of rounds of etching, when the condition of the interior of the chamber 106 reaches a threshold, etc. In some embodiments, a separate pasting procedure need not be performed; the metal redeposition in the chamber 106 that may occur during metal etch may provide adequate pasting.

Features formed using the metal etch tools and methods disclosed herein may be included in any suitable electronic component. FIGS. 10-14 illustrate various examples of apparatuses that may include features formed using the metal etch tools and methods disclosed herein.

FIG. 10 is a top view of a wafer 1500 and dies 1502 that may include features formed using the metal etch tools and methods disclosed herein. The wafer 1500 may be composed of semiconductor material and may include one or more dies 1502 having IC structures formed on a surface of the wafer 1500. Each of the dies 1502 may be a repeating unit of a semiconductor product that includes any suitable IC. After the fabrication of the semiconductor product is complete, the wafer 1500 may undergo a singulation process in which the dies 1502 are separated from one another to provide discrete “chips” of the semiconductor product. The die 1502 may include one or more transistors (e.g., some of the transistors 1640 of FIG. 11, discussed below) and/or supporting circuitry to route electrical signals to the transistors, as well as any other IC components. In some embodiments, metal interconnects that route electrical signals in the die 1502 may be at least partially formed using the metal etch tools and methods disclosed herein. In some embodiments, the wafer 1500 or the die 1502 may include a memory device (e.g., a random access memory (RAM) device, such as a static RAM (SRAM) device, a magnetic RAM (MRAM) device, a resistive RAM (RRAM) device, a conductive-bridging RAM (CBRAM) device, etc.), a logic device (e.g., an AND, OR, NAND, or NOR gate), or any other suitable circuit element. Multiple ones of these devices may be combined on a single die 1502. For example, a memory array formed by multiple memory devices may be formed on a same die 1502 as a processing device (e.g., the processing device 1802 of FIG. 14) or other logic that is configured to store information in the memory devices or execute instructions stored in the memory array. In some embodiments, memory devices and/or logic devices may be at least partially formed using the metal etch tools and methods disclosed herein. For example, the metal etch tools and methods disclosed herein may be utilized to form MRAM devices, which may include a large number of layers containing nonvolatile-forming etch products (e.g., platinum). In some embodiments, the metal etch tools and methods disclosed herein may be used to subtractively pattern copper in MRAM devices.

FIG. 11 is a side, cross-sectional view of an IC device 1600 that may include features formed using the metal etch tools and methods disclosed herein. One or more of the IC devices 1600 may be included in one or more dies 1502 (FIG. 10). The IC device 1600 may be formed on a substrate 1602 (e.g., the wafer 1500 of FIG. 10) and may be included in a die (e.g., the die 1502 of FIG. 10). The substrate 1602 may be a semiconductor substrate composed of semiconductor material systems including, for example, n-type or p-type materials systems (or a combination of both). The substrate 1602 may include, for example, a crystalline substrate formed using a bulk silicon or an SOI substructure. In some embodiments, the substrate 1602 may be formed using alternative materials, which may or may not be combined with silicon, that include but are not limited to germanium, indium antimonide, lead telluride, indium arsenide, indium phosphide, gallium arsenide, or gallium antimonide. Further materials classified as group II-VI, III-V, or IV may also be used to form the substrate 1602. Although a few examples of materials from which the substrate 1602 may be formed are described here, any material that may serve as a foundation for an IC device 1600 may be used. The substrate 1602 may be part of a singulated die (e.g., the dies 1502 of FIG. 10) or a wafer (e.g., the wafer 1500 of FIG. 10).

The IC device 1600 may include one or more device layers 1604 disposed on the substrate 1602. The device layer 1604 may include features of one or more transistors 1640 (e.g., metal oxide semiconductor field-effect transistors (MOSFETs)) formed on the substrate 1602. The device layer 1604 may include, for example, one or more source and/or drain (S/D) regions 1620, a gate 1622 to control current flow in the transistors 1640 between the S/D regions 1620, and one or more S/D contacts 1624 to route electrical signals to/from the S/D regions 1620. The transistors 1640 may include additional features not depicted for the sake of clarity, such as device isolation regions, gate contacts, and the like. The transistors 1640 are not limited to the type and configuration depicted in FIG. 11 and may include a wide variety of other types and configurations such as, for example, planar transistors, non-planar transistors, or a combination of both. Planar transistors may include bipolar junction transistors (BJT), heterojunction bipolar transistors (HBT), or high-electron-mobility transistors (HEMT). Non-planar transistors may include FinFET transistors, such as double-gate transistors or tri-gate transistors, and wrap-around or all-around gate transistors, such as nanoribbon and nanowire transistors.

Each transistor 1640 may include a gate 1622 formed of at least two layers, a gate dielectric and a gate electrode. The gate dielectric may include one layer or a stack of layers. The one or more layers may include silicon oxide, silicon dioxide, silicon carbide, and/or a high-k dielectric material. The high-k dielectric material may include elements such as hafnium, silicon, oxygen, titanium, tantalum, lanthanum, aluminum, zirconium, barium, strontium, yttrium, lead, scandium, niobium, and zinc. Examples of high-k materials that may be used in the gate dielectric include, but are not limited to, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and lead zinc niobate. In some embodiments, an annealing process may be carried out on the gate dielectric to improve its quality when a high-k material is used.

The gate electrode may be formed on the gate dielectric and may include at least one p-type work function metal or n-type work function metal, depending on whether the transistor 1640 is to be a p-type metal oxide semiconductor (PMOS) or an n-type metal oxide semiconductor (NMOS) transistor. In some implementations, the gate electrode may consist of a stack of two or more metal layers, where one or more metal layers are work function metal layers and at least one metal layer is a fill metal layer. Further metal layers may be included for other purposes, such as a barrier layer. For a PMOS transistor, metals that may be used for the gate electrode include, but are not limited to, ruthenium, palladium, platinum, cobalt, nickel, conductive metal oxides (e.g., ruthenium oxide), and any of the metals discussed below with reference to an NMOS transistor (e.g., for work function tuning). For an NMOS transistor, metals that may be used for the gate electrode include, but are not limited to, hafnium, zirconium, titanium, tantalum, aluminum, alloys of these metals, carbides of these metals (e.g., hafnium carbide, zirconium carbide, titanium carbide, tantalum carbide, and aluminum carbide), and any of the metals discussed above with reference to a PMOS transistor (e.g., for work function tuning).

In some embodiments, when viewed as a cross-section of the transistor 1640 along the source-channel-drain direction, the gate electrode may consist of a U-shaped structure that includes a bottom portion substantially parallel to the surface of the substrate and two sidewall portions that are substantially perpendicular to the top surface of the substrate. In other embodiments, at least one of the metal layers that form the gate electrode may simply be a planar layer that is substantially parallel to the top surface of the substrate and does not include sidewall portions substantially perpendicular to the top surface of the substrate. In other embodiments, the gate electrode may consist of a combination of U-shaped structures and planar, non-U-shaped structures. For example, the gate electrode may consist of one or more U-shaped metal layers formed atop one or more planar, non-U-shaped layers.

In some embodiments, a pair of sidewall spacers may be formed on opposing sides of the gate stack to bracket the gate stack. The sidewall spacers may be formed from materials such as silicon nitride, silicon oxide, silicon carbide, silicon nitride doped with carbon, and silicon oxynitride. Processes for forming sidewall spacers are well known in the art and generally include deposition and etching process steps. In some embodiments, a plurality of spacer pairs may be used; for instance, two pairs, three pairs, or four pairs of sidewall spacers may be formed on opposing sides of the gate stack.

The S/D regions 1620 may be formed within the substrate 1602 adjacent to the gate 1622 of each transistor 1640. The S/D regions 1620 may be formed using an implantation/diffusion process or an etching/deposition process, for example. In the former process, dopants such as boron, aluminum, antimony, phosphorous, or arsenic may be ion-implanted into the substrate 1602 to form the S/D regions 1620. An annealing process that activates the dopants and causes them to diffuse farther into the substrate 1602 may follow the ion-implantation process. In the latter process, the substrate 1602 may first be etched to form recesses at the locations of the S/D regions 1620. An epitaxial deposition process may then be carried out to fill the recesses with material that is used to fabricate the S/D regions 1620. In some implementations, the S/D regions 1620 may be fabricated using a silicon alloy such as silicon germanium or silicon carbide. In some embodiments, the epitaxially deposited silicon alloy may be doped in situ with dopants such as boron, arsenic, or phosphorous. In some embodiments, the S/D regions 1620 may be formed using one or more alternate semiconductor materials such as germanium or a group III-V material or alloy. In further embodiments, one or more layers of metal and/or metal alloys may be used to form the S/D regions 1620.

Electrical signals, such as power and/or input/output (I/O) signals, may be routed to and/or from the devices (e.g., the transistors 1640) of the device layer 1604 through one or more interconnect layers disposed on the device layer 1604 (illustrated in FIG. 11 as interconnect layers 1606-1610). For example, electrically conductive features of the device layer 1604 (e.g., the gate 1622 and the S/D contacts 1624) may be electrically coupled with the interconnect structures 1628 of the interconnect layers 1606-1610. The one or more interconnect layers 1606-1610 may form a metallization stack (also referred to as an “ILD stack”) 1619 of the IC device 1600. In some embodiments, some or all of the interconnect structures 1628 in a metallization stack 1619 (e.g., the interconnect structures 1628 of the lowest interconnect layer 1606, “M0,” and/or the interconnect structures 1628 of the second-lowest interconnect layer 1608, “M1”) may be subtractively patterned using the metal etch tools and methods disclosed herein.

The interconnect structures 1628 may be arranged within the interconnect layers 1606-1610 to route electrical signals according to a wide variety of designs (in particular, the arrangement is not limited to the particular configuration of interconnect structures 1628 depicted in FIG. 11). Although a particular number of interconnect layers 1606-1610 is depicted in FIG. 11, embodiments of the present disclosure include IC devices having more or fewer interconnect layers than depicted.

In some embodiments, the interconnect structures 1628 may include lines 1628a and/or vias 1628b filled with an electrically conductive material such as a metal. The lines 1628a may be arranged to route electrical signals in a direction of a plane that is substantially parallel with a surface of the substrate 1602 upon which the device layer 1604 is formed. For example, the lines 1628a may route electrical signals in a direction in and out of the page from the perspective of FIG. 11. The vias 1628b may be arranged to route electrical signals in a direction of a plane that is substantially perpendicular to the surface of the substrate 1602 upon which the device layer 1604 is formed. In some embodiments, the vias 1628b may electrically couple lines 1628a of different interconnect layers 1606-1610 together.

The interconnect layers 1606-1610 may include a dielectric material 1626 disposed between the interconnect structures 1628, as shown in FIG. 11. In some embodiments, the dielectric material 1626 disposed between the interconnect structures 1628 in different ones of the interconnect layers 1606-1610 may have different compositions; in other embodiments, the composition of the dielectric material 1626 between different interconnect layers 1606-1610 may be the same.

A first interconnect layer 1606 may be formed above the device layer 1604. In some embodiments, the first interconnect layer 1606 may include lines 1628a and/or vias 1628b, as shown. The lines 1628a of the first interconnect layer 1606 may be coupled with contacts (e.g., the S/D contacts 1624) of the device layer 1604.

A second interconnect layer 1608 may be formed above the first interconnect layer 1606. In some embodiments, the second interconnect layer 1608 may include vias 1628b to couple the lines 1628a of the second interconnect layer 1608 with the lines 1628a of the first interconnect layer 1606. Although the lines 1628a and the vias 1628b are structurally delineated with a line within each interconnect layer (e.g., within the second interconnect layer 1608) for the sake of clarity, the lines 1628a and the vias 1628b may be structurally and/or materially contiguous (e.g., simultaneously filled during a dual damascene process) in some embodiments.

A third interconnect layer 1610 (and additional interconnect layers, as desired) may be formed in succession on the second interconnect layer 1608 according to similar techniques and configurations described in connection with the second interconnect layer 1608 or the first interconnect layer 1606. In some embodiments, the interconnect layers that are “higher up” in the metallization stack 1619 in the IC device 1600 (i.e., farther away from the device layer 1604) may be thicker.

The IC device 1600 may include a solder resist material 1634 (e.g., polyimide or similar material) and one or more conductive contacts 1636 formed on the interconnect layers 1606-1610. In FIG. 11, the conductive contacts 1636 are illustrated as taking the form of bond pads. The conductive contacts 1636 may be electrically coupled with the interconnect structures 1628 and configured to route the electrical signals of the transistor(s) 1640 to other external devices. For example, solder bonds may be formed on the one or more conductive contacts 1636 to mechanically and/or electrically couple a chip including the IC device 1600 with another component (e.g., a circuit board). The IC device 1600 may include additional or alternate structures to route the electrical signals from the interconnect layers 1606-1610; for example, the conductive contacts 1636 may include other analogous features (e.g., posts) that route the electrical signals to external components.

FIG. 12 is a side, cross-sectional view of an example IC package 1650 that may include features formed using the metal etch tools and methods disclosed herein. In some embodiments, the IC package 1650 may be a system-in-package (SiP).

The package substrate 1652 may be formed of a dielectric material (e.g., a ceramic, a buildup film, an epoxy film having filler particles therein, glass, an organic material, an inorganic material, combinations of organic and inorganic materials, embedded portions formed of different materials, etc.), and may have conductive pathways extending through the dielectric material between the face 1672 and the face 1674, or between different locations on the face 1672, and/or between different locations on the face 1674. These conductive pathways may take the form of any of the interconnect structures 1628 discussed above with reference to FIG. 11.

The package substrate 1652 may include conductive contacts 1663 that are coupled to conductive pathways (not shown) through the package substrate 1652, allowing circuitry within the dies 1656 and/or the interposer 1657 to electrically couple to various ones of the conductive contacts 1664 (or to other devices included in the package substrate 1652, not shown).

The IC package 1650 may include an interposer 1657 coupled to the package substrate 1652 via conductive contacts 1661 of the interposer 1657, first-level interconnects 1665, and the conductive contacts 1663 of the package substrate 1652. The first-level interconnects 1665 illustrated in FIG. 12 are solder bumps, but any suitable first-level interconnects 1665 may be used. In some embodiments, no interposer 1657 may be included in the IC package 1650; instead, the dies 1656 may be coupled directly to the conductive contacts 1663 at the face 1672 by first-level interconnects 1665. More generally, one or more dies 1656 may be coupled to the package substrate 1652 via any suitable structure (e.g., (e.g., a silicon bridge, an organic bridge, one or more waveguides, one or more interposers, wirebonds, etc.).

The IC package 1650 may include one or more dies 1656 coupled to the interposer 1657 via conductive contacts 1654 of the dies 1656, first-level interconnects 1658, and conductive contacts 1660 of the interposer 1657. The conductive contacts 1660 may be coupled to conductive pathways (not shown) through the interposer 1657, allowing circuitry within the dies 1656 to electrically couple to various ones of the conductive contacts 1661 (or to other devices included in the interposer 1657, not shown). The first-level interconnects 1658 illustrated in FIG. 12 are solder bumps, but any suitable first-level interconnects 1658 may be used. As used herein, a “conductive contact” may refer to a portion of conductive material (e.g., metal) serving as an interface between different components; conductive contacts may be recessed in, flush with, or extending away from a surface of a component, and may take any suitable form (e.g., a conductive pad or socket).

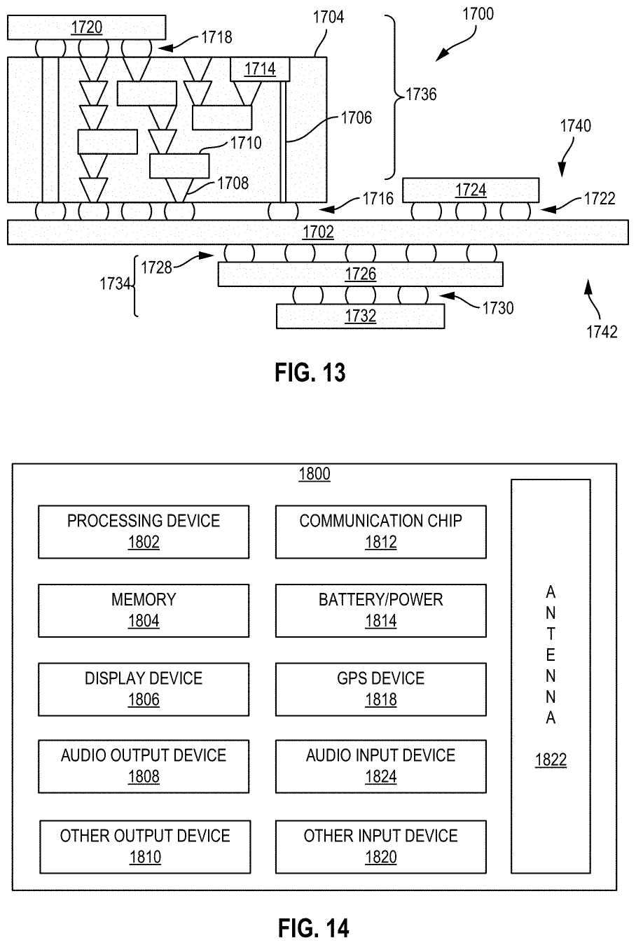

In some embodiments, an underfill material 1666 may be disposed between the package substrate 1652 and the interposer 1657 around the first-level interconnects 1665, and a mold compound 1668 may be disposed around the dies 1656 and the interposer 1657 and in contact with the package substrate 1652. In some embodiments, the underfill material 1666 may be the same as the mold compound 1668. Example materials that may be used for the underfill material 1666 and the mold compound 1668 are epoxy mold materials, as suitable. Second-level interconnects 1670 may be coupled to the conductive contacts 1664. The second-level interconnects 1670 illustrated in FIG. 12 are solder balls (e.g., for a ball grid array arrangement), but any suitable second-level interconnects 16770 may be used (e.g., pins in a pin grid array arrangement or lands in a land grid array arrangement). The second-level interconnects 1670 may be used to couple the IC package 1650 to another component, such as a circuit board (e.g., a motherboard), an interposer, or another IC package, as known in the art and as discussed below with reference to FIG. 13.

The dies 1656 may take the form of any of the embodiments of the die 1502 discussed herein (e.g., may include any of the embodiments of the IC device 1600). For example, in some embodiments, the dies 1656 may include features formed using the metal etch tools and methods disclosed herein. In embodiments in which the IC package 1650 includes multiple dies 1656, the IC package 1650 may be referred to as a multi-chip package (MCP). The dies 1656 may include circuitry to perform any desired functionality. For example, or more of the dies 1656 may be logic dies (e.g., silicon-based dies), and one or more of the dies 1656 may be memory dies (e.g., high bandwidth memory).

Although the IC package 1650 illustrated in FIG. 12 is a flip chip package, other package architectures may be used. For example, the IC package 1650 may be a ball grid array (BGA) package, such as an embedded wafer-level ball grid array (eWLB) package. In another example, the IC package 1650 may be a wafer-level chip scale package (WLCSP) or a panel fanout (FO) package. Although two dies 1656 are illustrated in the IC package 1650 of FIG. 12, an IC package 1650 may include any desired number of dies 1656. An IC package 1650 may include additional passive components, such as surface-mount resistors, capacitors, and inductors disposed on the first face 1672 or the second face 1674 of the package substrate 1652, or on either face of the interposer 1657. More generally, an IC package 1650 may include any other active or passive components known in the art.

FIG. 13 is a side, cross-sectional view of an IC device assembly 1700 that may include one or more IC packages or other electronic components (e.g., a die) having features formed using the metal etch tools and methods disclosed herein. The IC device assembly 1700 includes a number of components disposed on a circuit board 1702 (which may be, e.g., a motherboard). The IC device assembly 1700 includes components disposed on a first face 1740 of the circuit board 1702 and an opposing second face 1742 of the circuit board 1702; generally, components may be disposed on one or both faces 1740 and 1742. Any of the IC packages discussed below with reference to the IC device assembly 1700 may take the form of any of the embodiments of the IC package 1650 discussed above with reference to FIG. 12.

In some embodiments, the circuit board 1702 may be a printed circuit board (PCB) including multiple metal layers separated from one another by layers of dielectric material and interconnected by electrically conductive vias. Any one or more of the metal layers may be formed in a desired circuit pattern to route electrical signals (optionally in conjunction with other metal layers) between the components coupled to the circuit board 1702. In other embodiments, the circuit board 1702 may be a non-PCB substrate.

The IC device assembly 1700 illustrated in FIG. 13 includes a package-on-interposer structure 1736 coupled to the first face 1740 of the circuit board 1702 by coupling components 1716. The coupling components 1716 may electrically and mechanically couple the package-on-interposer structure 1736 to the circuit board 1702, and may include solder balls (as shown in FIG. 13), male and female portions of a socket, an adhesive, an underfill material, and/or any other suitable electrical and/or mechanical coupling structure.

The package-on-interposer structure 1736 may include an IC package 1720 coupled to an package interposer 1704 by coupling components 1718. The coupling components 1718 may take any suitable form for the application, such as the forms discussed above with reference to the coupling components 1716. Although a single IC package 1720 is shown in FIG. 13, multiple IC packages may be coupled to the package interposer 1704; indeed, additional interposers may be coupled to the package interposer 1704. The package interposer 1704 may provide an intervening substrate used to bridge the circuit board 1702 and the IC package 1720. The IC package 1720 may be or include, for example, a die (the die 1502 of FIG. 10), an IC device (e.g., the IC device 1600 of FIG. 11), or any other suitable component. Generally, the package interposer 1704 may spread a connection to a wider pitch or reroute a connection to a different connection. For example, the package interposer 1704 may couple the IC package 1720 (e.g., a die) to a set of BGA conductive contacts of the coupling components 1716 for coupling to the circuit board 1702. In the embodiment illustrated in FIG. 13, the IC package 1720 and the circuit board 1702 are attached to opposing sides of the package interposer 1704; in other embodiments, the IC package 1720 and the circuit board 1702 may be attached to a same side of the package interposer 1704. In some embodiments, three or more components may be interconnected by way of the package interposer 1704.

In some embodiments, the package interposer 1704 may be formed as a PCB, including multiple metal layers separated from one another by layers of dielectric material and interconnected by electrically conductive vias. In some embodiments, the package interposer 1704 may be formed of an epoxy resin, a fiberglass-reinforced epoxy resin, an epoxy resin with inorganic fillers, a ceramic material, or a polymer material such as polyimide. In some embodiments, the package interposer 1704 may be formed of alternate rigid or flexible materials that may include the same materials described above for use in a semiconductor substrate, such as silicon, germanium, and other group III-V and group IV materials. The package interposer 1704 may include metal lines 1710 and vias 1708, including but not limited to through-silicon vias (TSVs) 1706. The package interposer 1704 may further include embedded devices 1714, including both passive and active devices. Such devices may include, but are not limited to, capacitors, decoupling capacitors, resistors, inductors, fuses, diodes, transformers, sensors, electrostatic discharge (ESD) devices, and memory devices. More complex devices such as RF devices, power amplifiers, power management devices, antennas, arrays, sensors, and microelectromechanical systems (MEMS) devices may also be formed on the package interposer 1704. The package-on-interposer structure 1736 may take the form of any of the package-on-interposer structures known in the art.

The IC device assembly 1700 may include an IC package 1724 coupled to the first face 1740 of the circuit board 1702 by coupling components 1722. The coupling components 1722 may take the form of any of the embodiments discussed above with reference to the coupling components 1716, and the IC package 1724 may take the form of any of the embodiments discussed above with reference to the IC package 1720.

The IC device assembly 1700 illustrated in FIG. 13 includes a package-on-package structure 1734 coupled to the second face 1742 of the circuit board 1702 by coupling components 1728. The package-on-package structure 1734 may include an IC package 1726 and an IC package 1732 coupled together by coupling components 1730 such that the IC package 1726 is disposed between the circuit board 1702 and the IC package 1732. The coupling components 1728 and 1730 may take the form of any of the embodiments of the coupling components 1716 discussed above, and the IC packages 1726 and 1732 may take the form of any of the embodiments of the IC package 1720 discussed above. The package-on-package structure 1734 may be configured in accordance with any of the package-on-package structures known in the art.

FIG. 14 is a block diagram of an example electrical device 1800 that may include features formed using the metal etch tools and methods disclosed herein. For example, any suitable ones of the components of the electrical device 1800 may include one or more of the IC device assemblies 1700, IC packages 1650, IC devices 1600, or dies 1502 disclosed herein. A number of components are illustrated in FIG. 14 as included in the electrical device 1800, but any one or more of these components may be omitted or duplicated, as suitable for the application. In some embodiments, some or all of the components included in the electrical device 1800 may be attached to one or more motherboards. In some embodiments, some or all of these components are fabricated onto a single system-on-a-chip (SoC) die.

Additionally, in various embodiments, the electrical device 1800 may not include one or more of the components illustrated in FIG. 14, but the electrical device 1800 may include interface circuitry for coupling to the one or more components. For example, the electrical device 1800 may not include a display device 1806, but may include display device interface circuitry (e.g., a connector and driver circuitry) to which a display device 1806 may be coupled. In another set of examples, the electrical device 1800 may not include an audio input device 1824 or an audio output device 1808, but may include audio input or output device interface circuitry (e.g., connectors and supporting circuitry) to which an audio input device 1824 or audio output device 1808 may be coupled.

The electrical device 1800 may include a processing device 1802 (e.g., one or more processing devices). As used herein, the term “processing device” or “processor” may refer to any device or portion of a device that processes electronic data from registers and/or memory to transform that electronic data into other electronic data that may be stored in registers and/or memory. The processing device 1802 may include one or more digital signal processors (DSPs), application-specific integrated circuits (ASICs), central processing units (CPUs), graphics processing units (GPUs), cryptoprocessors (specialized processors that execute cryptographic algorithms within hardware), server processors, or any other suitable processing devices. The electrical device 1800 may include a memory 1804, which may itself include one or more memory devices such as volatile memory (e.g., dynamic random access memory (DRAM)), nonvolatile memory (e.g., read-only memory (ROM)), flash memory, solid state memory, and/or a hard drive. In some embodiments, the memory 1804 may include memory that shares a die with the processing device 1802. This memory may be used as cache memory and may include embedded dynamic random access memory (eDRAM) or spin transfer torque magnetic random access memory (STT-MRAM).

In some embodiments, the electrical device 1800 may include a communication chip 1812 (e.g., one or more communication chips). For example, the communication chip 1812 may be configured for managing wireless communications for the transfer of data to and from the electrical device 1800. The term “wireless” and its derivatives may be used to describe circuits, devices, systems, methods, techniques, communications channels, etc., that may communicate data through the use of modulated electromagnetic radiation through a nonsolid medium. The term does not imply that the associated devices do not contain any wires, although in some embodiments they might not.

The communication chip 1812 may implement any of a number of wireless standards or protocols, including but not limited to Institute for Electrical and Electronic Engineers (IEEE) standards including Wi-Fi (IEEE 802.11 family), IEEE 802.16 standards (e.g., IEEE 802.16-2005 Amendment), Long-Term Evolution (LTE) project along with any amendments, updates, and/or revisions (e.g., advanced LTE project, ultra mobile broadband (UMB) project (also referred to as “3GPP2”), etc.). IEEE 802.16 compatible Broadband Wireless Access (BWA) networks are generally referred to as WiMAX networks, an acronym that stands for Worldwide Interoperability for Microwave Access, which is a certification mark for products that pass conformity and interoperability tests for the IEEE 802.16 standards. The communication chip 1812 may operate in accordance with a Global System for Mobile Communication (GSM), General Packet Radio Service (GPRS), Universal Mobile Telecommunications System (UMTS), High Speed Packet Access (HSPA), Evolved HSPA (E-HSPA), or LTE network. The communication chip 1812 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). The communication chip 1812 may operate in accordance with Code Division Multiple Access (CDMA), Time Division Multiple Access (TDMA), Digital Enhanced Cordless Telecommunications (DECT), Evolution-Data Optimized (EV-DO), and derivatives thereof, as well as any other wireless protocols that are designated as 3G, 4G, 5G, and beyond. The communication chip 1812 may operate in accordance with other wireless protocols in other embodiments. The electrical device 1800 may include an antenna 1822 to facilitate wireless communications and/or to receive other wireless communications (such as AM or FM radio transmissions).

In some embodiments, the communication chip 1812 may manage wired communications, such as electrical, optical, or any other suitable communication protocols (e.g., the Ethernet). As noted above, the communication chip 1812 may include multiple communication chips. For instance, a first communication chip 1812 may be dedicated to shorter-range wireless communications such as Wi-Fi or Bluetooth, and a second communication chip 1812 may be dedicated to longer-range wireless communications such as global positioning system (GPS), EDGE, GPRS, CDMA, WiMAX, LTE, EV-DO, or others. In some embodiments, a first communication chip 1812 may be dedicated to wireless communications, and a second communication chip 1812 may be dedicated to wired communications.

The electrical device 1800 may include battery/power circuitry 1814. The battery/power circuitry 1814 may include one or more energy storage devices (e.g., batteries or capacitors) and/or circuitry for coupling components of the electrical device 1800 to an energy source separate from the electrical device 1800 (e.g., AC line power).

The electrical device 1800 may include a display device 1806 (or corresponding interface circuitry, as discussed above). The display device 1806 may include any visual indicators, such as a heads-up display, a computer monitor, a projector, a touchscreen display, a liquid crystal display (LCD), a light-emitting diode display, or a flat panel display.

The electrical device 1800 may include an audio output device 1808 (or corresponding interface circuitry, as discussed above). The audio output device 1808 may include any device that generates an audible indicator, such as speakers, headsets, or earbuds.

The electrical device 1800 may include an audio input device 1824 (or corresponding interface circuitry, as discussed above). The audio input device 1824 may include any device that generates a signal representative of a sound, such as microphones, microphone arrays, or digital instruments (e.g., instruments having a musical instrument digital interface (MIDI) output).

The electrical device 1800 may include a GPS device 1818 (or corresponding interface circuitry, as discussed above). The GPS device 1818 may be in communication with a satellite-based system and may receive a location of the electrical device 1800, as known in the art.

The electrical device 1800 may include an other output device 1810 (or corresponding interface circuitry, as discussed above). Examples of the other output device 1810 may include an audio codec, a video codec, a printer, a wired or wireless transmitter for providing information to other devices, or an additional storage device.

The electrical device 1800 may include an other input device 1820 (or corresponding interface circuitry, as discussed above). Examples of the other input device 1820 may include an accelerometer, a gyroscope, a compass, an image capture device, a keyboard, a cursor control device such as a mouse, a stylus, a touchpad, a bar code reader, a Quick Response (QR) code reader, any sensor, or a radio frequency identification (RFID) reader.

The electrical device 1800 may have any desired form factor, such as a handheld or mobile electrical device (e.g., a cell phone, a smart phone, a mobile internet device, a music player, a tablet computer, a laptop computer, a netbook computer, an ultrabook computer, a personal digital assistant (PDA), an ultra mobile personal computer, etc.), a desktop electrical device, a server device or other networked computing component, a printer, a scanner, a monitor, a set-top box, an entertainment control unit, a vehicle control unit, a digital camera, a digital video recorder, or a wearable electrical device. In some embodiments, the electrical device 1800 may be any other electronic device that processes data.

The following paragraphs provide various examples of the embodiments disclosed herein.

Example 1 is a metal etch tool, including: a chamber; an electrode inside the chamber; and a target material inside the chamber, wherein the electrode and the target material have a same material composition.

Example 2 includes the subject matter of Example 1, and further specifies that the electrode and the target material include copper.

Example 3 includes the subject matter of Example 1, and further specifies that the electrode and the target material include platinum.

Example 4 includes the subject matter of any of Examples 1-3, and further includes: a pedestal inside the chamber, wherein the pedestal is to provide a sample surface.

Example 5 includes the subject matter of Example 4, and further specifies that the electrode is between the target material and the pedestal.

Example 6 includes the subject matter of Example 5, and further specifies that the electrode is substantially planar.

Example 7 includes the subject matter of any of Examples 5-6, and further specifies that the electrode has a coil shape.

Example 8 includes the subject matter of any of Examples 5-6, and further specifies that the electrode has a serpentine shape.

Example 9 includes the subject matter of Example 4, and further specifies that the electrode is not between the target material and the pedestal.

Example 10 includes the subject matter of Example 9, and further specifies that the electrode has a helical coil shape.

Example 11 includes the subject matter of Example 9, and further specifies that the electrode has a band shape.

Example 12 includes the subject matter of any of Examples 4-11, and further includes: a collimator between the target material and the pedestal.

Example 13 includes the subject matter of Example 12, and further specifies that the electrode is between the target material and the collimator.

Example 14 includes the subject matter of Example 12, and further specifies that the electrode is not between the target material and the collimator.

Example 15 includes the subject matter of any of Examples 4-14, and further specifies that the pedestal is part of an electrostatic chuck.

Example 16 includes the subject matter of Example 15, and further includes: an alternating current (AC) source coupled to the electrostatic chuck, wherein the AC source is to generate AC current in a frequency range between 50 kilohertz and 100 megahertz.

Example 17 includes the subject matter of any of Examples 1-16, and further includes: a gas source coupled to the chamber.

Example 18 includes the subject matter of Example 17, and further specifies that the gas source includes CH₃ or C₂H₆.

Example 19 includes the subject matter of any of Examples 1-18, and further includes: a direct current (DC) source coupled to the target material.

Example 20 includes the subject matter of any of Examples 1-19, and further includes: an alternating current (AC) source coupled to the electrode.

Example 21 includes the subject matter of Example 20, and further specifies that the AC source is to generate AC current in a frequency range between 50 kilohertz and 100 megahertz.

Example 22 includes the subject matter of any of Examples 1-21, and further includes: a sensor inside the chamber.

Example 23 includes the subject matter of Example 22, and further specifies that the sensor is a gas sensor.

Example 24 includes the subject matter of any of Examples 22-23, and further includes: control circuitry, wherein the sensor is coupled to the control circuitry by an optical communication link.

Example 25 includes the subject matter of Example 24, and further specifies that the control circuitry is outside the chamber.

Example 26 is an integrated circuit (IC) component, including a metallization layer that includes a first metal feature, a first trench, a second metal feature, wherein the first trench is between the first metal feature and the second metal feature, a second trench, and a third metal feature, wherein the second trench is between the second metal feature and the third metal feature; wherein the first trench has an aspect ratio between 2:1 and 5:1, the second trench has an aspect ratio between 2:1 and 5:1, and a pitch of the first trench and the second trench is less than 40 nanometers.

Example 27 includes the subject matter of Example 26, and further specifies that the pitch of the first trench and the second trench is less than 30 nanometers.

Example 28 includes the subject matter of any of Examples 26-27, and further specifies that the aspect ratio of the first trench is between 3:1 and 5:1, and the aspect ratio of the second trench is between 3:1 and 5:1.

Example 29 includes the subject matter of any of Examples 26-28, and further specifies that the first metal feature is a metal line, the second metal feature is a metal line, and the third metal feature is a metal line.

Example 30 includes the subject matter of any of Examples 26-29, and further specifies that sidewalls of the first trench are angled and sidewalls of the second trench are angled.

Example 31 includes the subject matter of Example 30, and further specifies that sidewalls of the first trench have an angle that is less than 90 degrees and greater than 82 degrees, and sidewalls of the second trench have an angle that is less than 90 degrees and greater than 82 degrees.

Example 32 includes the subject matter of any of Examples 26-31, and further specifies that the metallization layer is a lowest metallization layer in a metallization stack.

Example 33 includes the subject matter of any of Examples 26-32, and further includes: a device layer, wherein interconnects in the metallization layer are conductively coupled to devices in the device layer.

Example 34 includes the subject matter of Example 33, and further specifies that the devices in the device layer include transistors.

Example 35 includes the subject matter of any of Examples 26-34, and further specifies that the IC component is a die.

Example 36 includes the subject matter of any of Examples 26-35, and further includes: conductive contacts at a face of the IC component.

Example 37 is a method of operating a metal etch tool, including: placing a sample in a chamber of the metal etch tool, wherein the sample includes a metal to be etched, the metal etch tool includes an electrode in the chamber, and the electrode includes the metal; and controlling the metal etch tool to etch the metal of the sample; and removing the etched sample from the chamber.

Example 38 includes the subject matter of Example 37, and further specifies that the metal is copper or platinum.

Example 39 includes the subject matter of any of Examples 37-38, and further includes: after removing the etched sample from the chamber, performing a pasting procedure within the chamber.

Example 40 includes the subject matter of Example 39, and further specifies that the pasting procedure includes placing an additional sample of the metal in the chamber and controlling the metal etch tool to paste the metal of the additional sample onto walls of the chamber.

Example 41 includes the subject matter of any of Examples 37-40, and further specifies that controlling the metal etch tool to etch the metal of the sample includes controlling the metal etch tool to bombard the metal of the sample with ions to knock atoms of the metal off the sample.

Example 42 includes the subject matter of Example 41, and further specifies that the atoms of the metal are knocked off the sample and onto an interior of the chamber.

Example 43 includes the subject matter of any of Examples 41-42, and further specifies that the atoms of the metal are knocked off the sample and onto the electrode.

Example 44 includes the subject matter of any of Examples 37-43, and further specifies that controlling the metal etch tool to etch the metal of the sample includes forming trenches in the metal of the sample, and the trenches have a pitch less than 40 nanometers.

Example 45 includes the subject matter of Example 44, and further specifies that individual trenches have an aspect ratio between 2:1 and 5:1.

Example 46 includes any of the metal etch tools disclosed herein.

Example 47 includes a metal etch tool having a metal electrode inside a chamber.

Example 48 includes a metal etch tool having a metal etch electrode between the target material and the pedestal.

Example 49 includes any of the metal etch methods disclosed herein.

Example 50 includes any of the subtractive metal patterning methods disclosed herein.

1. A metal etch tool, comprising:
a chamber;
an electrode inside the chamber; and
a target material inside the chamber, wherein the electrode and the target material have a same material composition.

2. The metal etch tool of claim 1, wherein the electrode and the target material include copper.

3. The metal etch tool of claim 1, wherein the electrode and the target material include platinum.

4. The metal etch tool of claim 1, further comprising:
a pedestal inside the chamber, wherein the pedestal is to provide a sample surface.

5. The metal etch tool of claim 4, wherein the electrode is between the target material and the pedestal.

6. The metal etch tool of claim 4, wherein the electrode is not between the target material and the pedestal.

7. The metal etch tool of claim 4, further comprising:
a collimator between the target material and the pedestal.

8. The metal etch tool of claim 7, wherein the electrode is between the target material and the collimator.

9. The metal etch tool of claim 7, wherein the electrode is not between the target material and the collimator.

10. The metal etch tool of claim 1, further comprising:
a gas source coupled to the chamber, wherein the gas source includes CH₃ or C₂H₆.

11. An integrated circuit (IC) component, comprising:
a metallization layer, including:
a first metal feature,
a first trench,
a second metal feature, wherein the first trench is between the first metal feature and the second metal feature,
a second trench, and
a third metal feature, wherein the second trench is between the second metal feature and the third metal feature;
wherein:
the first trench has an aspect ratio between 2:1 and 5:1,
the second trench has an aspect ratio between 2:1 and 5:1, and
a pitch of the first trench and the second trench is less than 40 nanometers.

12. The IC component of claim 11, wherein the pitch of the first trench and the second trench is less than 30 nanometers.

13. The IC component of claim 11, wherein the aspect ratio of the first trench is between 3:1 and 5:1, and the aspect ratio of the second trench is between 3:1 and 5:1.

14. The IC component of claim 11, wherein the first metal feature is a metal line, the second metal feature is a metal line, and the third metal feature is a metal line.

15. The IC component of claim 11, wherein sidewalls of the first trench are angled and sidewalls of the second trench are angled.

16. The IC component of claim 15, wherein sidewalls of the first trench have an angle that is less than 90 degrees and greater than 82 degrees, and sidewalls of the second trench have an angle that is less than 90 degrees and greater than 82 degrees.

17. The IC component of claim 11, wherein the metallization layer is a lowest metallization layer in a metallization stack.

18. A method of operating a metal etch tool, comprising:
placing a sample in a chamber of the metal etch tool, wherein the sample includes a metal to be etched, the metal etch tool includes an electrode in the chamber, and the electrode includes the metal; and
controlling the metal etch tool to etch the metal of the sample; and
removing the etched sample from the chamber.

19. The method of claim 18, further comprising:
after removing the etched sample from the chamber, performing a pasting procedure within the chamber.

20. The method of claim 18, wherein controlling the metal etch tool to etch the metal of the sample includes controlling the metal etch tool to bombard the metal of the sample with ions to knock atoms of the metal off the sample, and wherein the atoms of the metal are knocked off the sample and onto an interior of the chamber and onto the electrode.
